(19) United States
(12) Patent Application Publication
(10) Pub. No.: US 2026/0059711 A1
(43) Pub. Date: Feb. 26, 2026

(54) THREE-DIMENSIONAL VAPOR CHAMBER MODULE, SERVER AND IMMERSION LIQUID COOLING SYSTEM

(71) Applicant: Wiwynn Corporation, New Taipei City (TW)

(72) Inventors: WEN AN CHEN, New Taipei City (TW); Yi Cheng, New Taipei City (TW); Tsung-Han Li, New Taipei City (TW)

(21) Appl. No.: 19/276,114

(22) Filed: Jul. 22, 2025

Related U.S. Application Data
(60) Provisional application No. 63/686,253, filed on Aug. 23, 2024.

(30) Foreign Application Priority Data
Feb. 7, 2025 (TW) 114104614

(51) Int. Cl. H05K 7/20

(52) U.S. Cl. CPC H05K 7/20336; H05K 7/20236; H05K 7/20254; H05K 7/20309; H05K 7/20318; H05K 7/20327; H05K 7/20781; H05K 7/20809

(57) ABSTRACT

A three-dimensional vapor chamber module is configured to be thermally coupled to a heat source. The three-dimensional vapor chamber module includes a first vapor chamber, a second vapor chamber, at least one first heat pipe and a plurality of boiling enhancement structures. The first vapor chamber has a first fluid chamber, and the first vapor chamber is configured to be thermally coupled to the heat source. The second vapor chamber has a second fluid chamber. The first heat pipe has a first fluid channel, and the first fluid channel communicates with the first fluid chamber and the second fluid chamber. The boiling enhancement structures are respectively disposed on the first vapor chamber and the second vapor chamber.

### CROSS-REFERENCE TO RELATED APPLICATIONS

This non-provisional application claims priority under 35 U.S.C. § 119 (a) on Provisional Application No(s). 63/686,253 filed in U.S.A. on Aug. 23, 2024, and Patent Application No(s). 114104614 filed in Taiwan, R.O.C. on Feb. 7, 2025, the entire contents of which are hereby incorporated by reference.

### TECHNICAL FIELD

The disclosure relates to a three-dimensional vapor chamber module, a server and an immersion liquid cooling system.

### BACKGROUND

Currently, the industry commonly uses heat dissipation components with boiling enhancement structures to be thermally coupled with electronic components and immersed in coolant. In this way, heat generated by the electronic components is conducted to the coolant, causing the coolant to undergo phase change and take heat away.

However, with the advancement and development of technology, the performance of the electronic components has become increasingly higher, leading to an increasing amount of heat generation. As a result, the heat transfer efficiency of the current heat dissipation components is gradually failing to meet the demand. Therefore, how to address the aforementioned issue is one of topics in this field.

### SUMMARY

The disclosure provides a three-dimensional vapor chamber module, a server and an immersion liquid cooling system which are capable of solving the issues that the heat transfer efficiency of the current heat dissipation components is gradually failing to meet the demand.

One embodiment of the disclosure provides a three-dimensional vapor chamber module. The three-dimensional vapor chamber module is configured to be thermally coupled to a heat source. The three-dimensional vapor chamber module includes a first vapor chamber, a second vapor chamber, at least one first heat pipe and a plurality of boiling enhancement structures. The first vapor chamber has a first fluid chamber, and the first vapor chamber is configured to be thermally coupled to the heat source. The second vapor chamber has a second fluid chamber. The first heat pipe has a first fluid channel, and the first fluid channel communicates with the first fluid chamber and the second fluid chamber. The boiling enhancement structures are respectively disposed on the first vapor chamber and the second vapor chamber.

Another embodiment of the disclosure provides a server. The server includes a motherboard and a three-dimensional vapor chamber module. The motherboard has a heat source. The three-dimensional vapor chamber module includes a first vapor chamber, a second vapor chamber, at least one first heat pipe and a plurality of boiling enhancement structures. The first vapor chamber has a first fluid chamber, and the first vapor chamber is thermally coupled to the heat source. The second vapor chamber has a second fluid chamber. The first heat pipe has a first fluid channel, and the first fluid channel communicates with the first fluid chamber and the second fluid chamber. The boiling enhancement structures are respectively disposed on the first vapor chamber and the second vapor chamber.

Still another embodiment of the disclosure provides an immersion liquid cooling system. The immersion liquid cooling system includes a tank and at least one server. The tank is configured to accommodate a coolant. The server is configured to be disposed in the tank and immersed by the coolant. The server includes a support component, a motherboard and a three-dimensional vapor chamber module. The motherboard is disposed on the support component and has a heat source. The three-dimensional vapor chamber module includes a first vapor chamber, a second vapor chamber, at least one first heat pipe and a plurality of boiling enhancement structures. The first vapor chamber has a first fluid chamber, and the first vapor chamber is thermally coupled to the heat source. The second vapor chamber has a second fluid chamber. The first heat pipe has a first fluid channel, and the first fluid channel communicates with the first fluid chamber and the second fluid chamber. The boiling enhancement structures are respectively disposed on the first vapor chamber and the second vapor chamber.

According to the three-dimensional vapor chamber module, the server and the immersion liquid cooling system as disclosed in the above embodiments, the first fluid channels of the first heat pipes communicate with the first fluid chamber of the first vapor chamber and the second fluid chamber of the second vapor chamber, and the boiling enhancement structures are respectively disposed on the first vapor chamber and the second vapor chamber, which can improve the heat transfer efficiency for dealing with the heat source with higher heat generation.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 shows a cross-sectional view of an immersion liquid cooling system according to some embodiments of the disclosure;

FIG. 2 shows a perspective view of a three-dimensional vapor chamber module according to some embodiments of the disclosure;

FIG. 3 shows a cross-sectional view of a three-dimensional vapor chamber module according to some embodiments of the disclosure;

FIG. 4 shows a cross-sectional view of an immersion liquid cooling system according to some embodiments of the disclosure;

FIG. 5 shows a cross-sectional view of a three-dimensional vapor chamber module according to some embodiments of the disclosure;

FIG. 6 shows a perspective view of a three-dimensional vapor chamber module according to some embodiments of the disclosure;

FIG. 7 shows a cross-sectional view of a three-dimensional vapor chamber module according to some embodiments of the disclosure; and

FIG. 8 shows a cross-sectional view of a three-dimensional vapor chamber module according to some embodiments of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

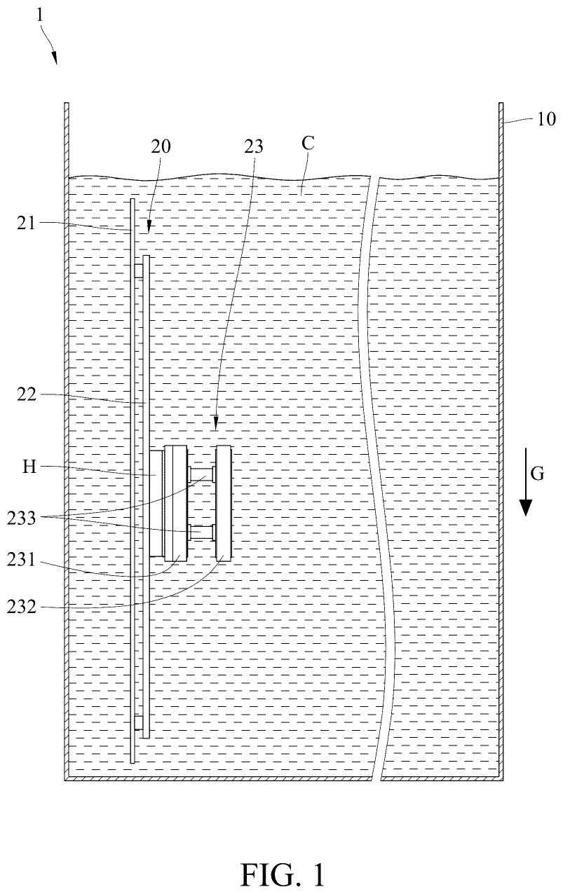

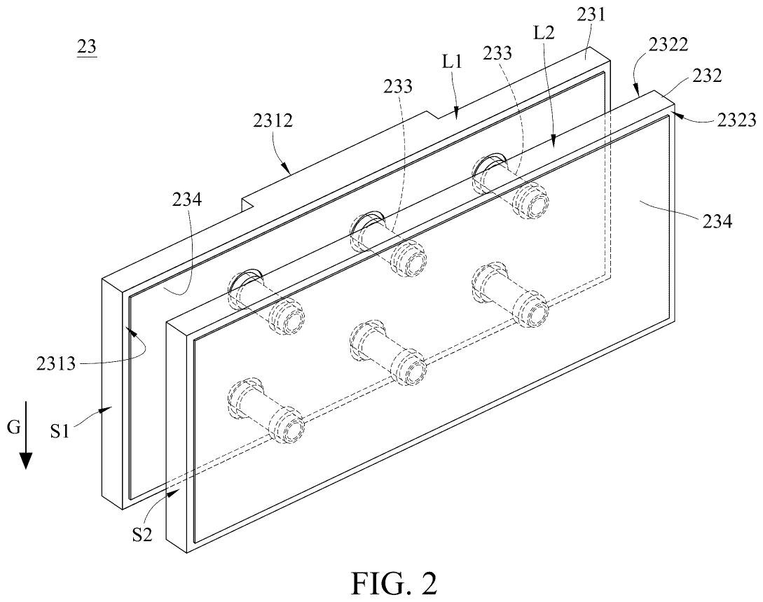

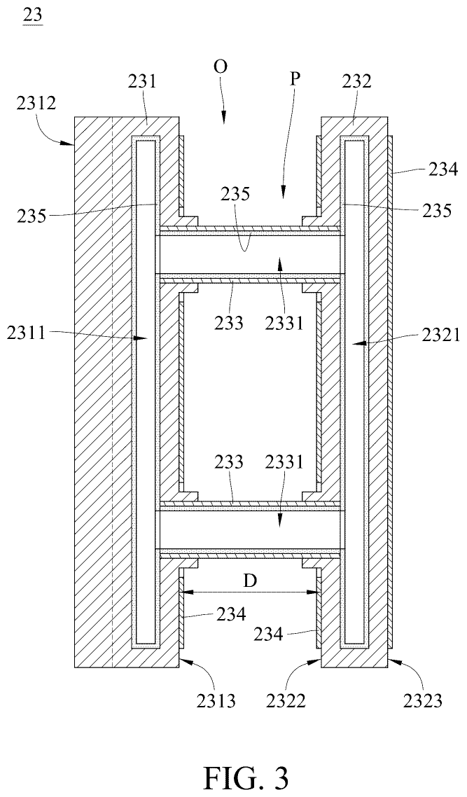

Referring to FIGS. 1 to 3, FIG. 1 shows a cross-sectional view of an immersion liquid cooling system 1 according to some embodiments of the disclosure, FIG. 2 shows a perspective view of a three-dimensional vapor chamber module 23 according to some embodiments of the disclosure, and FIG. 3 shows a cross-sectional view of the three-dimensional vapor chamber module 23 according to some embodiments of the disclosure. The structural features of FIGS. 1 to 3 can be applied to other embodiments of the disclosure.

The immersion liquid cooling system 1 includes a tank 10 and at least one server 20. The tank 10 is configured to accommodate a coolant C. The server 20 is configured to be disposed in the tank 10 and immersed by the coolant C. The server 20 includes a support component 21, a motherboard 22 and a three-dimensional vapor chamber module 23. The motherboard 22 is disposed on the support component 21 and has a heat source H. The three-dimensional vapor chamber module 23 includes a first vapor chamber 231, a second vapor chamber 232, at least one first heat pipe 233 and a plurality of boiling enhancement structures 234. The first vapor chamber 231 has a first fluid chamber 2311, and the first vapor chamber 231 is thermally coupled to the heat source H. The second vapor chamber 232 has a second fluid chamber 2321. The first heat pipe 233 has a first fluid channel 2331, and the first fluid channel 2331 communicates with the first fluid chamber 2311 and the second fluid chamber 2321. The boiling enhancement structures 234 are respectively disposed on the first vapor chamber 231 and the second vapor chamber 232.

In some embodiments, the support component 21 may be a tray or a frame, but the disclosure is no limited thereto. In some embodiments, the heat source H of the motherboard 22 may be a CPU or a GPU, but the disclosure is not limited thereto.

In some embodiments, the first vapor chamber 231 has a thermally coupling surface 2312 and a first heat dissipation surface 2313 facing away from each other. The thermally coupling surface 2312 is configured to be thermally coupled to the heat source H. The second vapor chamber 232 has a second heat dissipation surface 2322 and a third heat dissipation surface 2323 facing away from each other. In some embodiments, the three-dimensional vapor chamber module 23 includes a plurality of first heat pipes 233. In some embodiments, the first vapor chamber 231 and the second vapor chamber 232 are arranged side by side and spaced apart from each other via the first heat pipes 233, and the second heat dissipation surface 2322 of the second vapor chamber 232 faces the first heat dissipation surface 2313 of the first vapor chamber 231. In other words, the first vapor chamber 231 and the second vapor chamber 232 are arranged to be a two-layer structure via the first heat pipes 233. In some embodiments, the first heat pipes 233 may be welded to the first vapor chamber 231 and the second vapor chamber 232.

In some embodiments, the first vapor chamber 231 and the second vapor chamber 232 are in a rectangular shape. The first vapor chamber 231 has a long side L1 and a short side S1, and the second vapor chamber 232 has a long side L2 and a short side S2. The short side S1 of the first vapor chamber 231 and the short side S2 of the second vapor chamber 232 are parallel to a direction G of gravity. In one embodiment, a channel P is formed between the first vapor chamber 231 and the second vapor chamber 232, and the channel P has an opening O facing upwards so as to allow air formed in the channel P to float upwards and pass through the opening O.

In some embodiments, the boiling enhancement structures 234 are respectively disposed on the first heat dissipation surface 2313 and at least one of the second heat dissipation surface 2322 and the third heat dissipation surface 2323. In some embodiments, the boiling enhancement structures 234 are respectively disposed on the third heat dissipation surface 2323 and the first heat dissipation surface 2313. In some embodiments, one of the boiling enhancement structures 234 may be further disposed on the second heat dissipation surface 2322. In other words, the boiling enhancement structures 234 are respectively disposed on the first heat dissipation surface 2313, the second heat dissipation surface 2322 and the third heat dissipation surface 2323.

The boiling enhancement structures 234 are to increase bubble nucleation sites, produce more boiling bubbles per unit time and increase the contact area with the coolant. Although each of the boiling enhancement structures shown in FIGS. 2 and 3 is simplified to a sheet, the boiling enhancement structure referred in the disclosure may actually include at least one of metal mesh structure, sheet-shaped fin structure, pin fin structure or sintered metal structure.

In some embodiments, a distance D between the second heat dissipation surface 2322 of the second vapor chamber 232 and the first heat dissipation surface 2313 of the first vapor chamber 231 is greater than or equal to 5 mm. In some embodiment, the distance D between the second heat dissipation surface 2322 of the second vapor chamber 232 and the first heat dissipation surface 2313 of the first vapor chamber 231 is smaller than or equal to 25 mm.

In some embodiment, the three-dimensional vapor chamber module 23 may further include a plurality of capillary structures 235. The capillary structures 235 are respectively disposed in the first fluid chamber 2311 of the first vapor chamber 231, the second fluid chamber 2321 of the second vapor chamber 232 and the first fluid channels 2331 of the first heat pipes 233. In some embodiment, the capillary structures 235 in the first fluid chamber 2311 and the second fluid chamber 2321 are connected to each other via the capillary structure 235 in the first fluid channel 2331.

In the aforementioned embodiments, after heat generated by the heat source H is conducted to the first vapor chamber 231, a working fluid (not shown) in the first fluid chamber 2311 of the first vapor chamber 231 vaporizes, and then the gas-phase working fluid flows to the second fluid chamber 2321 of the second vapor chamber 232 through the first fluid channels 2331 of the first heat pipes 233, such that heat is conducted to the first heat pipes 233 and the second vapor chamber 232. The boiling enhancement structures 234 on the first vapor chamber 231 and the second vapor chamber 232 perform heat exchange with the coolant C in the tank 10, such that the coolant C near the boiling enhancement structures 234 is boiling, thereby producing bubbles. Then, the gas-phase working fluid in the second fluid chamber 2321 of the second vapor chamber 232 is condensed to the liquid-phase working fluid, and the liquid-phase working fluid flows back to the first fluid chamber 2311 of the first vapor chamber 231 through the capillary structures 235.

In the aforementioned embodiments, the first fluid channel 2331 of the first heat pipe 233 communicates with the first fluid chamber 2311 of the first vapor chamber 231 and the second fluid chamber 2321 of the second vapor chamber 232, and the boiling enhancement structures 234 are respectively disposed on the first vapor chamber 231 and the second vapor chamber 232, which can improve the heat transfer efficiency for dealing with the heat source H with higher heat generation.

Additionally, by configuring the first vapor chamber 231 and the second vapor chamber 232 into the two-layer structure through the first heat pipes 233, and arranging the boiling enhancement structures 234 on the first heat dissipation surface 2313, the second heat dissipation surface 2322 and the third heat dissipation surface 2323, the heat transfer efficiency can be further improved. Furthermore, according to the pool boiling correlation proposed by Rohsenow, the total heat dissipation surface area is inversely proportional to the superheat degree, where the superheat degree refers to the temperature difference between the surface temperature required to boil the coolant C and the boiling point of the coolant C. Table 1 presents the superheat degrees of a planar vapor chamber with boiling enhancement structures and the three-dimensional vapor chamber module 23 in the aforementioned embodiment with two layers provided with the boiling enhancement structures 234.

TABLE 1

| | Number | Number of | | |
|---|---|---|---|---|
| | of layer | boiling | superheat | |
| | of vapor | enhancement | degree | Improvement |
| | chamber | structure | (° C.) | rate |
| Planar vapor | 1 | 1 | 10 | — |
| chamber with | | | | |
| boiling | | | | |
| enhancement | | | | |
| structure | | | | |
| three-dimensional | 2 | 3 | 10/3 = 3.3 | (10 − 3.3)/10*100% = |
| vapor chamber | | | | 67% |
| module 23 with | | | | |
| two layers | | | | |
| provided with | | | | |
| boiling | | | | |
| enhancement | | | | |
| structures 234 | | | | |

From table 1, it can be understood that the three-dimensional vapor chamber module 23 with two layers provided with the boiling enhancement structures 234 can reduce the superheat degree, thereby improving the heat transfer efficiency.

On the other hand, since the configuration of the three-dimensional vapor chamber module 23 with two layers provided the boiling enhancement structures 234 enables 67% reduction in the overall surface temperature, the thermal resistance between the three-dimensional vapor chamber module 23 and the coolant C can be reduced from 0.01° C. to 0.0033° C. Under the condition that the heat source H operates at the same temperature, the 10 planar vapor chamber with boiling enhancement structures can only allow the power of the heat source H to reach 1000W, while the three-dimensional vapor chamber module 23 in the aforementioned embodiment can allow the power of the heat source H to reach 1340W, thus achieving approximately 34% improvement in performance.

Note that the first heat dissipation surface 2313, the second heat dissipation surface 2322 and the third heat dissipation surface 2323 are not restricted to be all provided with the boiling enhancement structures 234. In one embodiment, only one of the second heat dissipation surface and the third heat dissipation surface may be provided with the boiling enhancement structure. In addition, the boiling enhancement structures are not restricted to being disposed on the heat dissipation surfaces of the first vapor chamber and the second vapor chamber. In some other embodiments, the boiling enhancement structures may be disposed on other surfaces of the first vapor chamber and the second vapor chamber.

In the aforementioned embodiment, the distance D between the second heat dissipation surface 2322 of the second vapor chamber 232 and the first heat dissipation surface 2313 of the first vapor chamber 231 is greater than or equal to 5 mm, which can prevent the first vapor chamber 231 and the second vapor chamber 232 from being too close to interfere the escape of the bubbles.

In the aforementioned embodiment, the distance D between the second heat dissipation surface 2322 of the second vapor chamber 232 and the first heat dissipation surface 2313 of the first vapor chamber 231 is smaller than or equal to 25 mm, which can prevent the distance D between the first vapor chamber 231 and the second vapor chamber 232 from being too large to adversely affect the heat transfer efficiency of the three-dimensional vapor chamber module 23.

Note that the distance D between the second heat dissipation surface 2322 of the second vapor chamber 232 and the first heat dissipation surface 2313 of the first vapor chamber 231 is not restricted to falling within the aforementioned range and may be modified according to actual requirements.

In the aforementioned embodiment, the short side S1 of the first vapor chamber 231 and the short side S2 of the second vapor chamber 232 are parallel to the direction G of gravity, which can shorten the escape path of the bubbles, thereby facilitate the bubbles to escape from the three-dimensional vapor chamber module 23 while helping to replenish the coolant C near the boiling enhancement structures 234 for forming new bubbles.

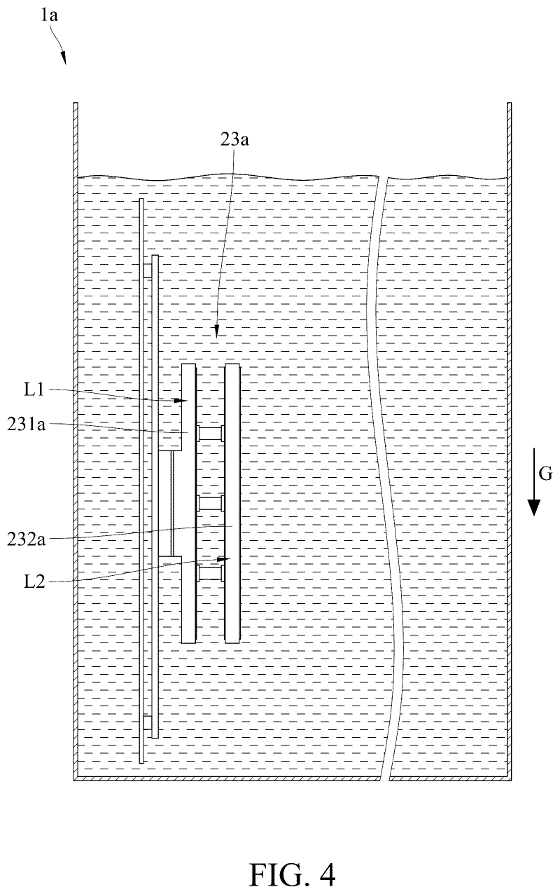

Note that the short side S1 of the first vapor chamber 231 and the short side S2 of the second vapor chamber 232 are not restricted to being parallel to the direction G of gravity. For example, referring to FIG. 4, FIG. 4 shows a cross-sectional view of an immersion liquid cooling system 1a according to some embodiments of the disclosure. The structural features of FIG. 4 can be applied to other embodiments of the disclosure.

In the embodiment of FIG. 4, a long side L1 of a first vapor chamber 231a and a long side L2 of a second vapor chamber 232a of a three-dimensional vapor chamber module 23a are parallel to a direction G of gravity. In other words, the first vapor chamber 231a and the second vapor chamber 232a are placed in a manner that the long sides L1 and L2 are parallel to the direction G of gravity.

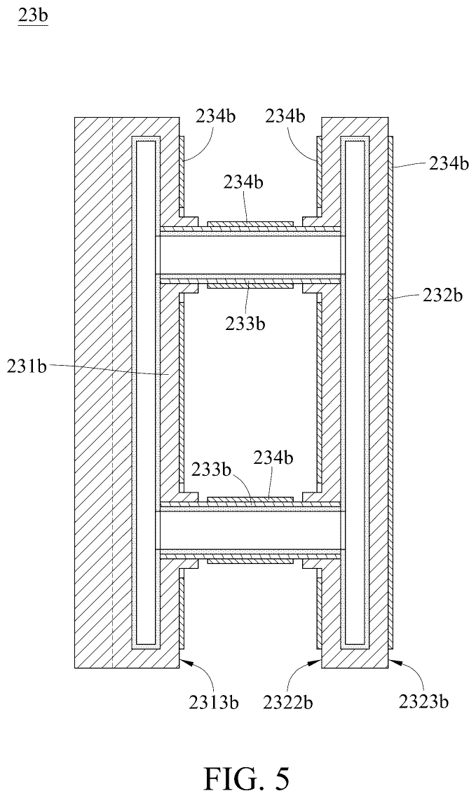

Then, referring to FIG. 5, FIG. 5 shows a cross-sectional view of a three-dimensional vapor chamber module 23b according to some embodiments of the disclosure. The structural features of FIG. 5 can be applied to other embodiments of the disclosure. For example, the three-dimensional vapor chamber module 23b can replace the three-dimensional vapor chamber modules shown in FIGS. 1 and 4.

In some embodiment, some of boiling enhancement structures 234b of the three-dimensional vapor chamber module 23b are further disposed on outer surfaces of first heat pipes 233b. In other words, the boiling enhancement structures 234b are respectively disposed on a first heat dissipation surface 2313b of a first vapor chamber 231b, a second heat dissipation surface 2322b and a third heat dissipation surface 2323b of a second vapor chamber 232b and the outer surfaces of the first heat pipes 233b.

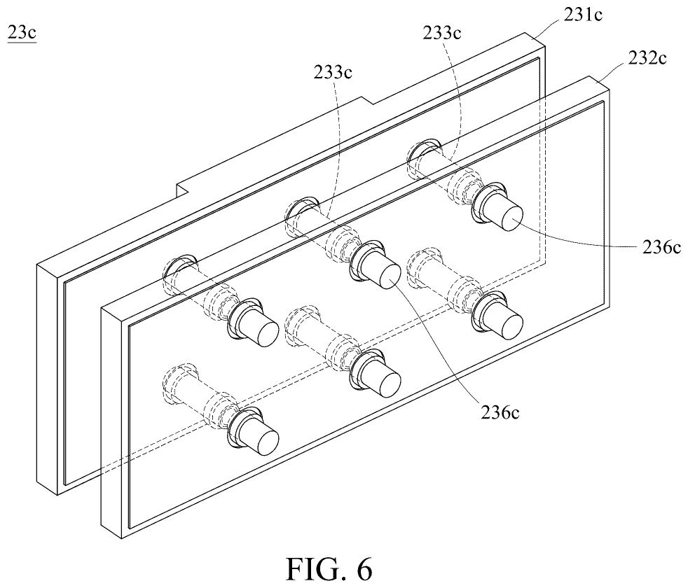

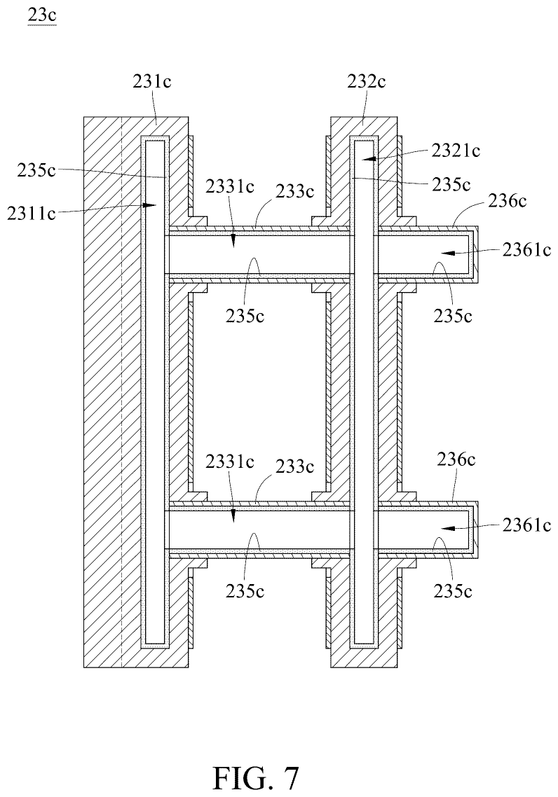

Then, referring to FIGS. 6 and 7, FIG. 6 shows a perspective view of a three-dimensional vapor chamber module 23c according to some embodiments of the disclosure, and FIG. 7 shows a cross-sectional view of the three-dimensional vapor chamber module 23c according to some embodiments of the disclosure. The structural features of FIGS. 6 and 7 can be applied to other embodiments of the disclosure. For example, the three-dimensional vapor chamber module 23c can replace the three-dimensional vapor chamber modules shown in FIGS. 1 and 4.

In the embodiment of FIGS. 6 and 7, the three-dimensional vapor chamber module 23c may further include a plurality of second heat pipes 236c. The second heat pipes 236c are disposed on one side of a second vapor chamber 232c located farther away from first heat pipes 233c. In other words, the second heat pipes 236c and the first heat pipes 233c are respectively disposed on two opposite sides of the second vapor chamber 232c. Each of the second heat piped 236c has a second fluid channel 2361c, and the second fluid channel 2361c communicates with a second fluid chamber 2321c of the second vapor chamber 232c. In addition, capillary structures 235c of the three-dimensional vapor chamber module 23c are respectively disposed in a first fluid chamber 2311c of a first vapor chamber 231c, the second fluid chamber 2321c of the second vapor chamber 232c, first fluid channels 2331c of the first heat pipes 233c and the second fluid channels 2361c of the second heat pipes 236c, and the capillary structures 235c are connected to one another.

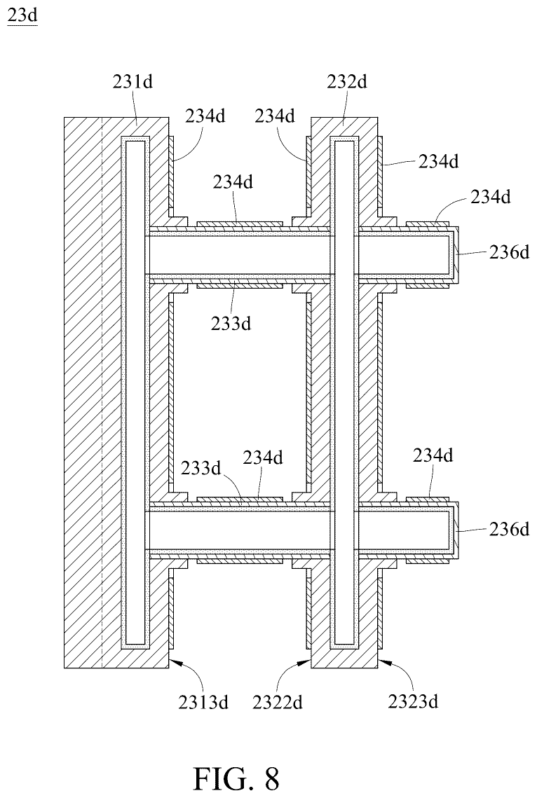

Then, referring to FIG. 8, FIG. 8 shows a cross-sectional view of a three-dimensional vapor chamber module 23d according to some embodiments of the disclosure. The structural features of FIG. 8 can be applied to other embodiments of the disclosure. For example, the three-dimensional vapor chamber module 23d can replace the three-dimensional vapor chamber modules shown in FIGS. 1 and 4.

In the embodiment of FIG. 8, boiling enhancement structures 234d of the three-dimensional vapor chamber module 23d are not only disposed on a first heat dissipation surface 2313d of a first vapor chamber 231d, a second heat dissipation surface 2322d and a third heat dissipation surface 2323d of a second vapor chamber 232d and outer surfaces of first heat pipes 233d, but also disposed on outer surfaces of second heat pipes 236d.

Note that the first heat dissipation surface 2313d, the second heat dissipation surface 2322d, the third heat dissipation surface 2323d, the outer surfaces of the first heat pipes 233d and the outer surfaces of the second heat pipes 236d are not restricted to being all provided with the boiling enhancement structures 234d. In one embodiment, the outer surfaces of the first heat pipes may not be provided with the boiling enhancement structures. In one embodiment, the outer surfaces of the second heat pipes may not be provided with the boiling enhancement structures. In another embodiment, only one of the second heat dissipation surface and the third heat dissipation surface may be provided with the boiling enhancement structure. Furthermore, the boiling enhancement structures are not restricted to being disposed on the heat dissipation surfaces of the first vapor chamber and the second vapor chamber. In some other embodiments, the boiling enhancement structures may be disposed on other surfaces of the first vapor chamber and the second vapor chamber.

In the aforementioned embodiments, the first vapor chamber and the second vapor chamber are arranged side by side and spaced apart from each other via the first heat pipes so as to form the two-layer structure, but the disclosure is not limited thereto. In some other embodiments, the first vapor chamber and the second vapor chamber may be arranged in other suitable manners.

According to the three-dimensional vapor chamber module, the server and the immersion liquid cooling system as disclosed in the above embodiments, the first fluid channels of the first heat pipes communicate with the first fluid chamber of the first vapor chamber and the second fluid chamber of the second vapor chamber, and the boiling enhancement structures are respectively disposed on the first vapor chamber and the second vapor chamber, which can improve the heat transfer efficiency for dealing with the heat source with higher heat generation.

Additionally, by configuring the first vapor chamber and the second vapor chamber into the two-layer structure through the first heat pipes, and arranging the boiling enhancement structures on the first heat dissipation surface, the second heat dissipation surface, the third heat dissipation surface and the outer surfaces of the first heat pipes, the heat transfer efficiency can be further improved.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A three-dimensional vapor chamber module, configured to be thermally coupled to a heat source, comprising:
a first vapor chamber, having a first fluid chamber, wherein the first vapor chamber is configured to be thermally coupled to the heat source;
a second vapor chamber, having a second fluid chamber;
at least one first heat pipe, having a first fluid channel, wherein the first fluid channel communicates with the first fluid chamber and the second fluid chamber; and
a plurality of boiling enhancement structures, respectively disposed on the first vapor chamber and the second vapor chamber.

2. The three-dimensional vapor chamber module according to claim 1, wherein the first vapor chamber has a thermally coupling surface and a first heat dissipation surface facing away from each other, the thermally coupling surface is configured to be thermally coupled to the heat source, the second vapor chamber has a second heat dissipation surface and a third heat dissipation surface facing away from each other, the plurality of boiling enhancement structures are respectively disposed on the first heat dissipation surface and at least one of the second heat dissipation surface and the third heat dissipation surface.

3. The three-dimensional vapor chamber module according to claim 2, wherein the first vapor chamber and the second vapor chamber are arranged side by side and spaced apart from each other via the at least one first heat pipe, the second heat dissipation surface of the second vapor chamber faces the first heat dissipation surface of the first vapor chamber, and the plurality of boiling enhancement structures are respectively disposed on the third heat dissipation surface and the first heat dissipation surface.

4. The three-dimensional vapor chamber module according to claim 3, wherein the plurality of boiling enhancement structures are respectively disposed on the first heat dissipation surface, the second heat dissipation surface and the third heat dissipation surface.

5. The three-dimensional vapor chamber module according to claim 4, wherein the plurality of boiling enhancement structures are respectively disposed on the first heat dissipation surface, the second heat dissipation surface, the third heat dissipation surface and an outer surface of the at least one first heat pipe.

6. The three-dimensional vapor chamber module according to claim 4, wherein a distance between the second heat dissipation surface of the second vapor chamber and the first heat dissipation surface of the first vapor chamber is greater than or equal to 5 mm.

7. The three-dimensional vapor chamber module according to claim 6, wherein the distance between the second heat dissipation surface of the second vapor chamber and the first heat dissipation surface of the first vapor chamber is smaller than or equal to 25 mm.

8. The three-dimensional vapor chamber module according to claim 3, further comprising at least one second heat pipe, wherein the at least one second heat pipe and the at least one first heat pipe are respectively disposed on two opposite sides of the second vapor chamber, the at least one second heat pipe has a second fluid channel, and the second fluid channel communicates with the second fluid chamber of the second vapor chamber.

9. The three-dimensional vapor chamber module according to claim 8, wherein the plurality of boiling enhancement structures are respectively disposed on the first heat dissipation surface, the second heat dissipation surface, the third heat dissipation surface, an outer surface of the at least one first heat pipe and an outer surface of the at least one second heat pipe.

10. The three-dimensional vapor chamber module according to claim 1, further comprising a plurality of capillary structures, wherein the plurality of capillary structures are respectively disposed in the first fluid chamber of the first vapor chamber, the second fluid chamber of the second vapor chamber and the first fluid channel of the at least one first heat pipe.

11. The three-dimensional vapor chamber module according to claim 10, wherein the plurality of capillary structures in the first fluid chamber, the second fluid chamber and the first fluid channel are connected to one another.

12. A server, comprising:
a motherboard, having a heat source; and
a three-dimensional vapor chamber module, comprising:
a first vapor chamber, having a first fluid chamber, wherein the first vapor chamber is thermally coupled to the heat source;
a second vapor chamber, having a second fluid chamber;
at least one first heat pipe, having a first fluid channel, wherein the first fluid channel communicates with the first fluid chamber and the second fluid chamber; and
a plurality of boiling enhancement structures, respectively disposed on the first vapor chamber and the second vapor chamber.

13. The server according to claim 12, wherein the first vapor chamber has a thermally coupling surface and a first heat dissipation surface facing away from each other, the thermally coupling surface is configured to be thermally coupled to the heat source, the second vapor chamber has a second heat dissipation surface and a third heat dissipation surface facing away from each other, the plurality of boiling enhancement structures are respectively disposed on the first heat dissipation surface and at least one of the second heat dissipation surface and the third heat dissipation surface.

14. The server according to claim 13, wherein the first vapor chamber and the second vapor chamber are arranged side by side and spaced apart from each other via the at least one first heat pipe, the second heat dissipation surface of the second vapor chamber faces the first heat dissipation surface of the first vapor chamber, and the plurality of boiling enhancement structures are respectively disposed on the third heat dissipation surface and the first heat dissipation surface.

15. The server according to claim 14, wherein the plurality of boiling enhancement structures are respectively disposed on the first heat dissipation surface, the second heat dissipation surface and the third heat dissipation surface.

16. The server according to claim 15, wherein a distance between the second heat dissipation surface of the second vapor chamber and the first heat dissipation surface of the first vapor chamber is greater than or equal to 5 mm.

17. The server according to claim 16, wherein the distance between the second heat dissipation surface of the second vapor chamber and the first heat dissipation surface of the first vapor chamber is smaller than or equal to 25 mm.

18. The server according to claim 14, wherein the three-dimensional vapor chamber module further comprises at least one second heat pipe, the at least one second heat pipe and the at least one first heat pipe are respectively disposed on two opposite sides of the second vapor chamber, the at least one second heat pipe has a second fluid channel, and the second fluid channel communicates with the second fluid chamber of the second vapor chamber.

19. The server according to claim 18, wherein the plurality of boiling enhancement structures are respectively disposed on the first heat dissipation surface, the second heat dissipation surface, the third heat dissipation surface, an outer surface of the at least one first heat pipe and an outer surface of the at least one second heat pipe.

20. An immersion liquid cooling system, comprising:
a tank, configured to accommodate a coolant; and
at least one server, configured to be disposed in the tank and immersed by the coolant, wherein the at least one server comprises:
a support component;
a motherboard, disposed on the support component and having a heat source; and
a three-dimensional vapor chamber module, comprising:
a first vapor chamber, having a first fluid chamber, wherein the first vapor chamber is thermally coupled to the heat source;
a second vapor chamber, having a second fluid chamber;
at least one first heat pipe, having a first fluid channel, wherein the first fluid channel communicates with the first fluid chamber and the second fluid chamber; and
a plurality of boiling enhancement structures, respectively disposed on the first vapor chamber and the second vapor chamber.

21. The immersion liquid cooling system according to claim 20, wherein a channel is formed between the first vapor chamber and the second vapor chamber, the channel has an opening facing upwards so as to allow air formed in the channel to float upwards and pass through the opening.

22. The immersion liquid cooling system according to claim 20, wherein the first vapor chamber has a thermally coupling surface and a first heat dissipation surface facing away from each other, the thermally coupling surface is configured to be thermally coupled to the heat source, the second vapor chamber has a second heat dissipation surface and a third heat dissipation surface facing away from each other, the plurality of boiling enhancement structures are respectively disposed on the first heat dissipation surface and at least one of the second heat dissipation surface and the third heat dissipation surface.

23. The immersion liquid cooling system according to claim 22, wherein the first vapor chamber and the second vapor chamber are arranged side by side and spaced apart from each other via the at least one first heat pipe, the second heat dissipation surface of the second vapor chamber faces the first heat dissipation surface of the first vapor chamber, and the plurality of boiling enhancement structures are respectively disposed on the third heat dissipation surface and the first heat dissipation surface.

24. The immersion liquid cooling system according to claim 23, wherein the plurality of boiling enhancement structures are respectively disposed on the first heat dissipation surface, the second heat dissipation surface and the third heat dissipation surface.

25. The immersion liquid cooling system according to claim 24, wherein a distance between the second heat dissipation surface of the second vapor chamber and the first heat dissipation surface of the first vapor chamber is greater than or equal to 5 mm.

26. The immersion liquid cooling system according to claim 25, wherein the distance between the second heat dissipation surface of the second vapor chamber and the first heat dissipation surface of the first vapor chamber is smaller than or equal to 25 mm.

27. The immersion liquid cooling system according to claim 20, wherein the first vapor chamber and the second vapor chamber are in a rectangular shape, and each of the first vapor chamber and the second vapor chamber has a long side and a short side, and the short side is parallel to a direction of gravity.
